(19) United States
(12) Patent Application Publication
(10) Pub. No.: US 2008/0135939 A1
(43) Pub. Date: Jun. 12, 2008

(54) Fabrication method of semiconductor package and structure thereof

(76) Inventors: Chi Chih Lin, Pingjhen City (TW); Bo Sun, Pingjhen City (TW); Hung Jen Wang, Gueishan Township (TW); Jen Feng Tseng, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/000,021

(22) Filed: Dec. 7, 2007

(30) Foreign Application Priority Data
Dec. 8, 2006 (TW) 95146075

(51) Int. Cl. H01L 23/62

(52) U.S. Cl. 257/355

(57) ABSTRACT

A fabrication method of semiconductor and a structure thereof are disclosed herein. The present invention includes: providing a substrate; disposing a mask on the substrate, wherein the mask has a plurality of patterned openings to expose portions of the substrate; forming a metal layer on the exposed portions of the substrate; forming a surface treatment layer on the metal layer; removing the mask; performing a chip package step; and removing the substrate and the metal layer to form a height difference of semiconductor package with pads. The characteristic of the height difference not only can increase the thickness of the solder materials but also can easily check the soldering status.

### BACKGROUND OF THE INVENTION

1. Field of the Invention

The present invention relates to a fabrication method of semiconductor package and a structure thereof. More particularly, the present invention relates to the fabrication method of semiconductor package and a structure thereof with pads having a height difference.

2. Description of the Prior Art

Along with the rapid progress of the computer and internet communication, the semiconductor products need to be multi-functional, portable, light, thin and small-sized to satisfy the customers' demand. Therefore, the industry of chip package has to develop towards the high accurate processes to comply with the requirements of high-power, high-density, lightness, thinness, compactness and mini-size. Besides, electronics packaging still needs high availability, good thermal performance to communicate signal and electrical power, to support good way to dissipate heat and to protect the structure.

The prior semiconductor fabrication process is to fabricate circuit on the substrate by etching, and then disposed the chip. Continuingly, electrically connect the chip and the circuit. After, utilize the molding compound covering element mentioned above and then etch the metal substrate. In order to dispose the bump connecting outside electricity on the circuit, the circuit needs to leave the circuit line in advance to perform the flow of electroplating the metal bump at the position of expecting to solder. Due to the etching step needed to control many essential factors, the etching result can be not control easily. The common issue is to product the phenomenon of undercut when etching and make the pattern transfer to the substrate imprecise. Later, electroplate the metal surface treatment layer. While bounding wire needs to bound wire on a curved surface, the yield of bounding wire is worse and the difficulty of the fabrication process is higher. Moreover, most prior package structure with soldering pad merely coats the solder material on the bottom of the soldering pad. After the surface mount technology (SMT), some issues happen, which are not easy to check the soldering status by eye. These issues all affect the yield of the chip package fabrication process and the faith of product.

Therefore, how to simplify the fabrication flow and raise the yield and the faith of fabrication is an important issue to fabricate thin products in semiconductor industry.

### SUMMARY OF THE INVENTION

One object of the present invention is to provide a fabrication method of semiconductor package and a structure thereof. The forming surface treatment layer of the present invention is plane, so as to not only raise the yield of bonding wire but also simplify the difficulty of bonding wire.

Another object of the present invention is to provide a fabrication method of semiconductor package and a structure thereof. The present invention forms a semiconductor package with pads having a height difference to increase the thickness of the solder material.

Another object of the present invention is to provide a fabrication method of semiconductor package and a structure thereof. The present invention can increase the thickness of solder material, besides the characteristic of the. height difference can check the soldering status.

In accordance with the above objectives, one embodiment of the present invention is providing a fabrication method of semiconductor package including: providing a substrate; disposing a mask on the substrate, wherein the mask has a plurality of patterned openings to expose portions of the substrate; forming a metal layer on the exposed portions of the substrate; forming a surface treatment layer on the metal layer; removing the mask; performing a chip package step; and removing the substrate and the metal layer to form a plurality of fillisters and to expose the surface treatment layer.

In accordance with the above objectives, another embodiment of the present invention is providing a fabrication method of semiconductor package including: providing a substrate; disposing a mask on the substrate, wherein the first mask has a plurality of patterned openings to expose portions of the substrate; forming a surface treatment layer on the exposed portions of substrate; removing the first mask; disposing a second mask to cover the surface treatment layer, wherein the second mask has a plurality of patterned openings to expose portions of substrate; forming a metal layer on the exposed portions of substrate; removing the second mask; performing a chip package step; and removing the substrate and the metal layer to form a plurality of fillisters and to expose a side of the surface treatment layer.

In accordance with the above objectives, another embodiment of the present invention is providing a fabrication method of semiconductor package including: providing a substrate; disposing a first mask on the substrate, wherein the first mask has a plurality of patterned openings to expose portions of the substrate; forming a surface treatment layer on the exposed portions of the substrate; removing the first mask; disposing a second mask to cover the surface treatment layer, wherein the second mask has a plurality of patterned openings to expose portions of the substrate; forming a metal layer on the exposed portions of said substrate; removing the second mask; performing a chip package step; and removing the substrate and the metal layer to form a plurality of fillisters and to expose the side of the surface treatment layer.

In accordance with the above objectives, another embodiment of the present invention is providing a structure of semiconductor package including: a surface treatment layer defining at least a chip carrier area and a plurality of conducting connection areas around each chip carrier area; at least a chip disposed on the chip carrier area and a conducting structure electrically connecting the chip and the conducting connection areas; and a molding compound covering directly the chip, conducting structure and the surface treatment layer, wherein a height difference is existed between the surface treatment layer and the molding compound.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A, FIG. 1B, FIG. 1C, FIG. 1D, FIG. 1E, FIG. 1F, FIG. 1G, and FIG. 1H are each step cross-section view schematic diagrams of the semiconductor package fabrication method in accordance with first embodiment of the present invention.

FIG. 2A, FIG. 2B, FIG. 2C, FIG. 2D, FIG. 2E, FIG. 2F, FIG. 2G, and FIG. 2H FIG. 2I, FIG. 2J-1 and FIG. 2J-2 are each step cross-section view schematic diagrams of the semiconductor package fabrication method in accordance with second embodiment of the present invention.

### DETAILED DESCRIPTION OF THE INVENTION

The detailed explanation of the present invention is described as following. The described preferred embodiments are presented for purposes of illustrations and description, and they are not intended to limit the scope of the present invention.

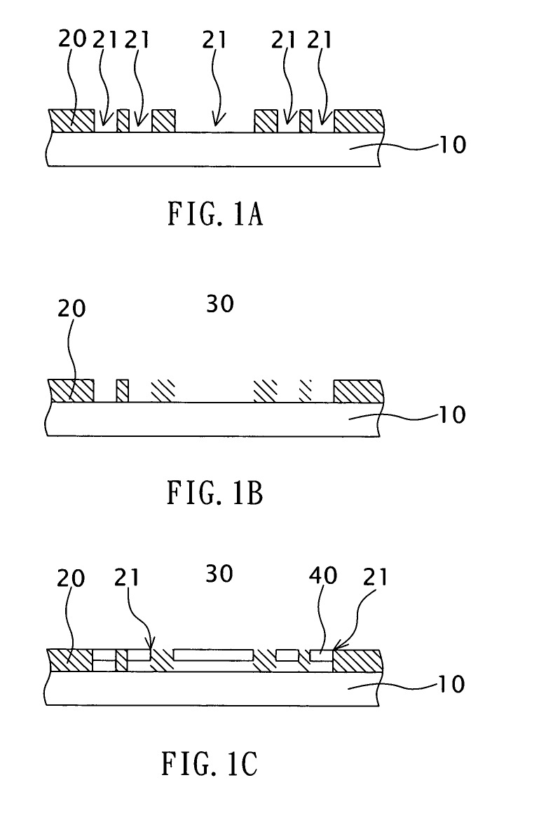

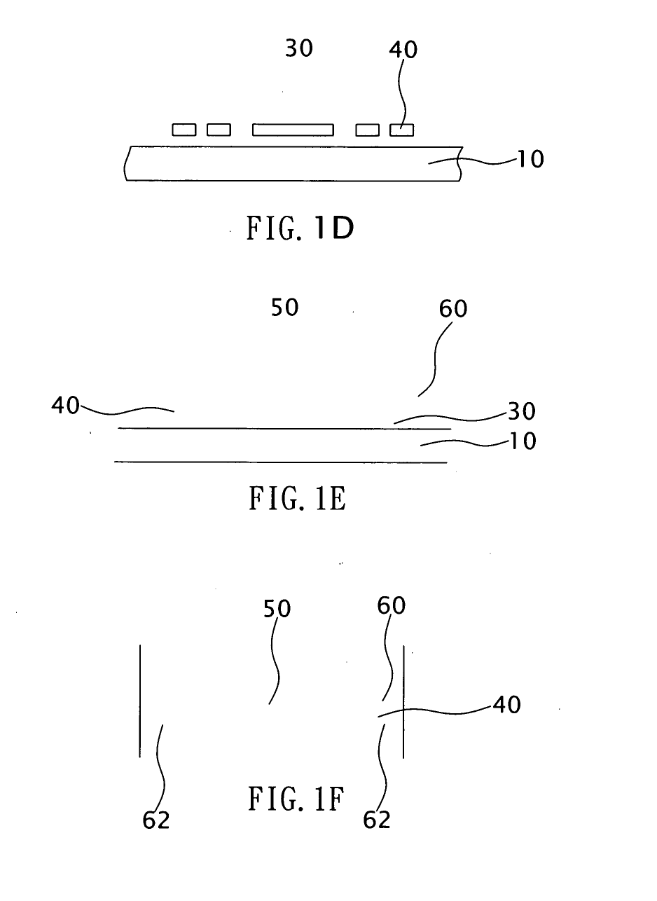

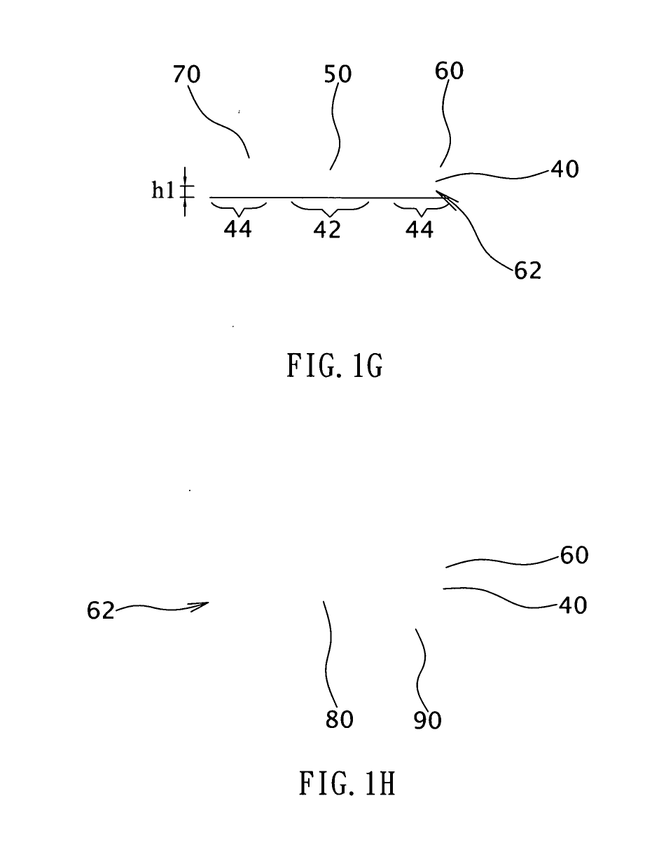

FIG. 1A to FIG. 1H are cross-sectional diagrams illustrating the fabrication method of a semiconductor package in accordance with a first embodiment of the present invention. First, please refer to FIG. 1A, a substrate 10 is provided and a mask 20 is disposed on the substrate 10, wherein the mask 20 has a plurality of patterned openings 21 to expose portions of the substrate 10. Next, please refer to the FIG. 1B, using the mask 20 as mask to form a metal layer 30, which is made of copper for example, on the exposed portions of the substrate 10. In one embodiment, the metal layer 30 is formed by electroplating, electroless plating or printing. Continuing, please refer to the FIG. 1C, forming a surface treatment layer 40 on the metal layer 30, wherein the patterned openings 21 is filled with the surface treatment layer 40 to form circuit. In one embodiment, the surface treatment layer 40 can be formed by electroplating, chemical electroplating or printing. The structure formed by the above fabrication process can simplify the difficulty of following wire bonding and raise the wire bonding quality. After, as shown in FIG. 1D, removing the mask 20 to remain the patterned circuit formed by the metal layer 30 and surface treatment layer 40 on the substrate 10. Further, please refer to the FIG. 1E, performing a chip package step. In one embodiment, the chip package step includes: disposing at least one chip 50 on the surface treatment layer 40; next, electrically connecting the chip 50 and the surface treatment layer 40; and forming a molding compound 60 by mold filling to cover the chip 50 separated from outside air. In one embodiment, the chip 50 and surface treatment layer 40 maybe electrically connect by wire bonding or flip chip. Finally, as shown in the FIG. 1F, removing the metal layer 30 and the substrate 10 to form a plurality of fillisters 62 and expose the surface treatment layer 40. In one embodiment, the metal layer 30 and the substrate 10 are removed by etching. In another embodiment, if the substrate 10 will be used repeatedly, the substrate can be removed in advance by shelling or other suit way and then the metal layer 30 is removed by etching.

In one embodiment, the mask 20 can be a photoresist layer with a plurality of patterned openings 21 (shown in FIG. 1A), wherein these patterned openings 21 can be formed by the laser direct imaging (LDI), lithography or image-transfer. Next, the metal layer 30 or the treatment layer 40 is formed on the substrate 10 through the patterned openings 21 (shown in FIG. 1A) of the mask 20 by the electroplating, electroless plating, chemical plating or printing. Understandably, the mask 20 is not limited in mentioned above. In another embodiment, the mask 20 can be a patterned plate. When fabricating the semiconductor packages with the same pattern, the patterned plate can be used repeatedly to lower the production cost.

Continuously, in one embodiment, after removing the substrate 10 and the metal layer 30, a dicing step is performed to form a plurality of semiconductor packages, wherein one of the semiconductor packages is shown in FIG. 1G As shown in FIG. 1G, the surface treatment layer 40 can define at least one chip carrier area 42 and a plurality of conducting connection areas 44, wherein the conducting connection areas 44 are around each chip carrier area 42, but not limited. At least one chip 50 is disposed on the chip carrier area 42 and a conducting structure 70 is used to electrically connect the chip 50 with the conducting connection area 44. In one embodiment, the conducting structure 70 includes at least one wire or at least one connecting pad to electrically connect the chip 50 and conducting connection area 44 by wire bonding. In another embodiment, the conducting structure 70 may be the metal bumps to electrically connect the chip 50 with the conducting connection area 44 by flip chip method. The molding compound 60, which is made of the epoxy or the other resin material, covers the chip 50, conducting structure 70 and the surface treatment layer 40 directly, wherein one side of the surface treatment layer 40 is exposed from the molding compound 60 and a height difference h1 is existed between the surface treatment layer 40 and the molding compound 60. Moreover, the carrier portion of semiconductor package only includes one surface treatment layer 40 to reach thin requirement.

In one embodiment, the material of treatment layer 40 is selected from the group consisting of gold, nickel, palladium, silver, copper, tin and lead. In another embodiment, the surface treatment layer 40 further includes a plurality of metal films whose material is selected from the group consisting of gold, nickel, palladium, silver, copper, tin and lead. One side of the surface treatment layer 40 electrically connects the chip 50 to expose one side of the molding compound 60 for electrically connecting other electrical device later. Hence the material of one side of metal film is metal which is convenient to wire bonding or flip chip to electrically connect the chip 50; the material of one side metal thin film exposed outside the molding compound 60 is metal supporting soldering or convenient to soldering. Therefore, two sides of the surface treatment layer 40 (one side electrically connecting the chip and the other soldering with electrical device) both can support fine connecting according to different requirement.

Please refer to the FIG. 1G, in this embodiment, a plurality of fillisters 62 form on the chip carrier area 42 and on the conducting connecting area 44 and exposes the surface treatment layer 40 to form the height difference h1 which supports filling solder material when soldering other electrical device later. As shown in the FIG. 1H, when soldering other electric device, the structure of semiconductor package further includes a plurality of soldering elements 80, such as the soldering material made of tin disposed on the exposed surface treatment layer 40 to conveniently solder other electrical device (such as circuit board 90 in figure). As shown in the figure, the fillister 62 is filled with the soldering element 80 to make soldering element 80 and the surface treatment layer 40 find electrically connecting, wherein the design of fillister 62 not only raise the quantity of filled soldering element 80 but also hence raise the product faith.

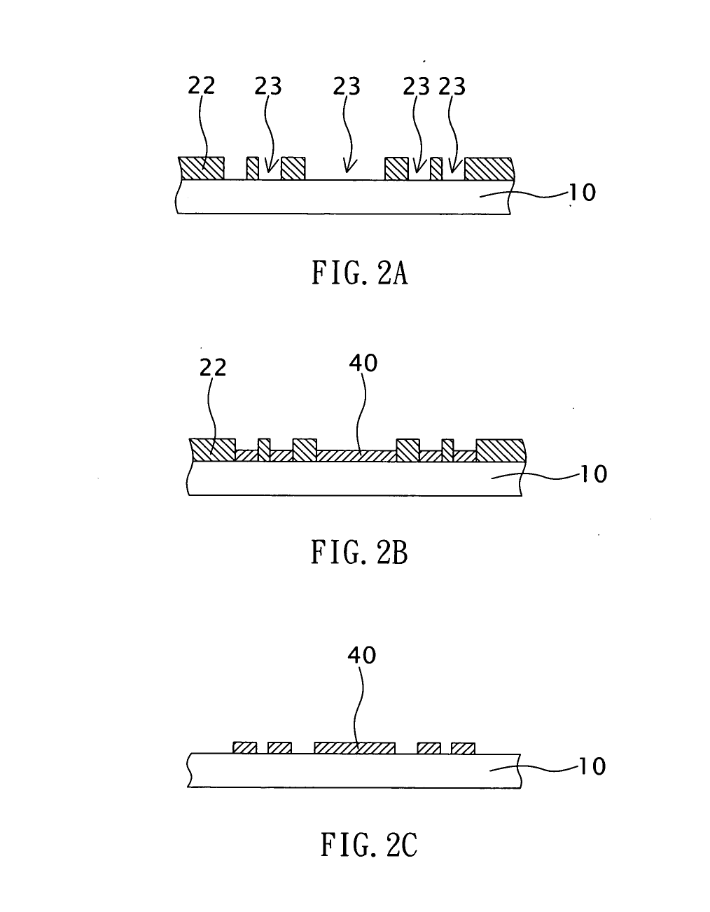

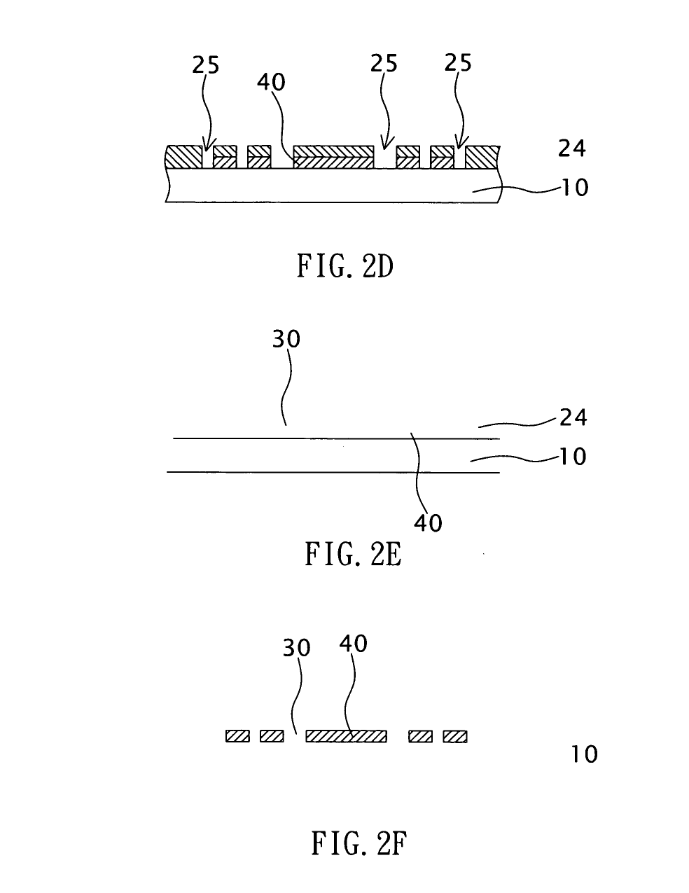

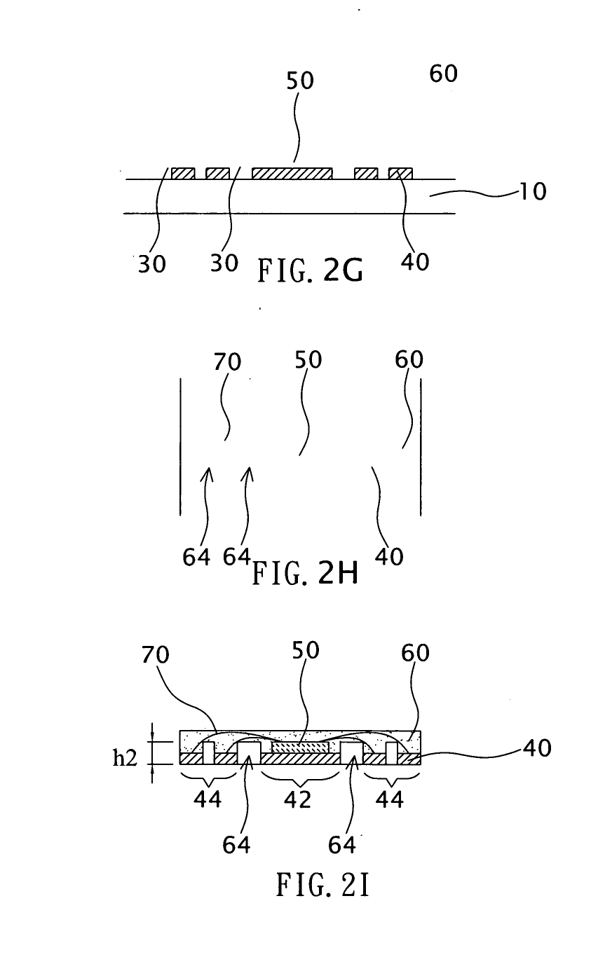

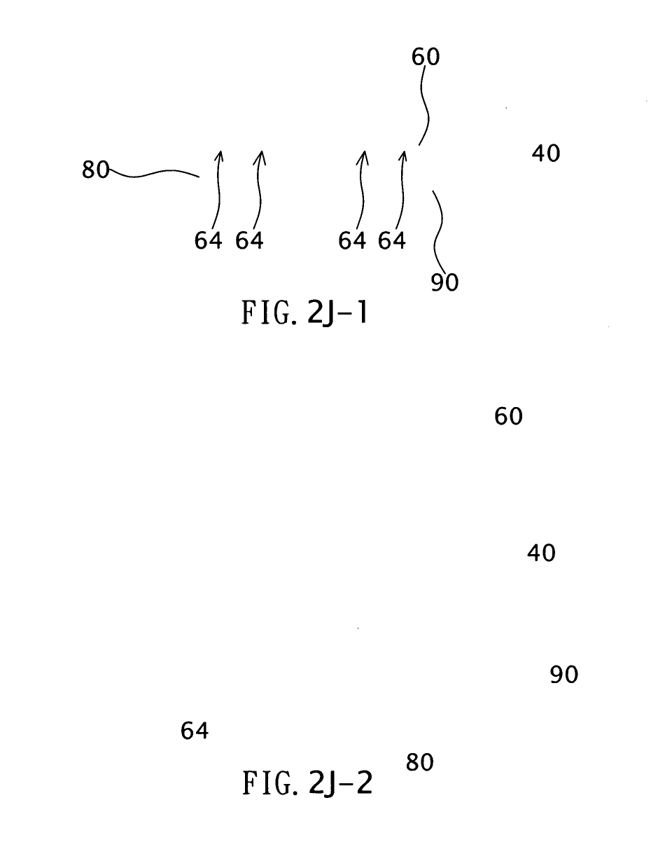

FIG. 2A to FIG. 2J-2 are each step cross-section view schematic diagrams of the semiconductor package fabrication method in accordance with the second embodiment of the present invention. As shown in FIG. 2A, first, providing a substrate 10 having a first mask such as the mask 22, wherein the mask 22 has a plurality of patterned openings 23 to expose portions of substrate 10. Continuously, please refer to FIG. 2B and FIG. 2C, the mask 22 is taken as mask to form a surface treatment layer 40 on the exposed substrate 10 and then removing the mask. After, as shown in FIG. 2D, disposing a second mask such as the mask 24 covers the treatment layer 40, wherein the mask 24 has a plurality of patterned openings 25 to expose portions of substrate 10. In one embodiment, the surface treatment layer 40 is whole or portion covered by the mask 24 and the patterned opening 25 merely exposed portions of substrate 10. Furthermore, please refer to FIG. 2E and the FIG. 2F, the mask 24 is taken as mask to form a metal layer 30 on exposed substrate 10 and the mask 24 is removed later. Next, performing a chip package step can finish the structure of semiconductor package shown in FIG. 2G. In this embodiment, the chip package step includes: disposing at least a chip 50 on the surface treatment layer 40 by the suitable way; electrically connecting the chip 50 and the surface treatment layer 40 by the bonding wire or flip chip; and utilizing the mold filling method to form a molding compound 60 covering the chip 50, the metal layer 30, the surface treatment layer 40; and portions of substrate 10 to separate the chip 50 from the outside air. Finally, the substrate 10 and the metal layer 30 are removed, please refer to the FIG. 2G and FIG. 2H, shown in the figure, the removed metal layer 30 forms a plurality of fillisters 64 to expose one side and side of the surface treatment layer 40.

Continuously, in one embodiment, the first mask, such as the mask 22, and the second mask, such as the mask 24, can be the patterned photoresist layer to form the metal layer 30 or the surface treatment layer 40 on the substrate 10 respectively through the patterned openings 23 and 24 (such as the FIG. 2A and FIG. 2D) on the masks 22 and 24 by the electroplating, electroless plating, chemical electroplating or printing. In one embodiment, the patterned openings 23 and 24 on the masks 22 and 24 (such shown as the FIG. 2A and FIG. 2D) can form by the laser direct imaging (LDI), lithography or image-transfer. How ever, understanding, the masks 22 and 24 are not limited here. In one embodiment, the masks 22 and 24 also can be patterned plate. In the same fabrication process of patterned design, the patterned plate can be used repeatedly to lower the fabrication process and the production cost.

The common point with above embodiment is the method of forming the metal layer 30 can use any of electroplating, printing and electroless plating; the method of forming surface treatment layer 40 can use the electroless plating printing, electroplating or chemical electroplating. In one embodiment, the surface treatment layer 40 can also include a plurality of metal films to conveniently electrically connecting the chip 50 and soldering other device. Further, removing the metal layer 30 and the substrate 10 by the etching method; besides, if the substrate 10 can be used repeatedly, it can also remove the substrate 10 by shelling method or other suitable methods and then remove the metal layer 30 by etching.

In one embodiment, after removing the substrate 10 and the metal layer 30, it further includes a dicing step to form a plurality of semiconductor packages shown as the FIG. 2I. The difference point from the first embodiment of semiconductor package structure is that a plurality of fillisters 64 formed around the chip carrier area 42 and the conducting connection area 44 to expose the side of surface treatment layer 40 and make the molding compound 60 inside the fillisters 64 and the surface treatment layer 40 form the height difference h2 shown as the figure. In another embodiment, please refer to the FIG. 2J-1 and FIG. 2J-2, the FIG. 2J-2 is the partial enlarging schematic diagram of FIG. 2J-1. The structure of semiconductor package further includes a plurality of soldering elements 80 disposed below the surface treatment layer 40 to conveniently solder with the semiconductor package structure outside electrical device on circuit board 90. As shown in FIG. 2J-2, the soldering element 80 covers one side of the surface treatment layer 40 through the fillister on molding compound 60, so as to greatly increase the thickness of soldering element 80 to raise the yield of fabrication process.

According to above description, one of the characteristic of the invention is to utilize patterned films or patterned plate as the mask to perform the fabrication of metal layer or the surface treatment layer. The fabrication process is elasticity and the same patterned design of fabrication process used tautologically to reduce the production cost; further, one characteristic of invention is that the height difference of the semiconductor package structure can utilize a plurality of fillisters with pads protruding or indenting to increase the thickness of the solder material; moreover, one characteristic of the invention is that in the carrier portion only includes the surface treatment layer ad equally meet the requirement of thin structure; another, the surface treatment layer also can include a plurality of metal films to support find bonding between the electrically connecting side and soldering side.

To sum up above description, the invention supports a method of semiconductor fabrication and a structure thereof. The formed surface treatment layer is a plate to increase the yield of bonding wire, besides, that can also simplify the difficulty of wire bonding. Further, the formed molding compound with pad having a height difference to increase the thickness of solder material, besides that and the characteristic of a height difference also conveniently checks the soldering status. Furthermore, by molding compound forms a plurality of fillisters to finish the height difference that make soldering full of fillister of molding compound or cover the side of surface treatment layer and raise the soldering faith.

What is claimed is:

1. A fabrication method of a semiconductor package, comprising:
providing a substrate;
disposing a mask on said substrate, wherein said mask has a plurality of patterned openings to expose portions of said substrate;
forming a metal layer on said exposed portions of said substrate;
forming a surface treatment layer on said metal layer;
removing said mask;
performing a chip package step; and
removing said substrate and said metal layer to form a plurality of fillisters and to expose said surface treatment layer.

2. The fabrication method of the semiconductor package according to claim 1, wherein said patterned openings are formed by laser direct imaging, lithography or image-transfer.

3. The fabrication method of the semiconductor package according to claim 1, wherein said metal layer is formed by electroplating, electroless plating or printing.

4. The fabrication method of the semiconductor package according to claim 1, wherein said surface treatment layer is formed by electroplating, chemical plating or printing.

5. The fabrication method of the semiconductor package according to claim 1, wherein said metal layer is removed by etching.

6. The fabrication method of the semiconductor package according to claim 1, wherein said chip package step comprises:
disposing at least a chip on said surface treatment layer;
electrically connecting said chip and said surface treatment layer; and
forming a molding compound to cover said chip.

7. The fabrication method of the semiconductor package according to claim 6, wherein said chip and said surface treatment layer are electrically connected by wire bonding or flip chip.

8. The fabrication method of the semiconductor package according to claim 1, further comprising a dicing step to form a plurality of semiconductor packages.

9. A fabrication method of a semiconductor package, comprising:
providing a substrate;
disposing a first mask on said substrate, wherein said first mask has a plurality of patterned openings to expose portions of said substrate;
forming a surface treatment layer on said exposed portions of said substrate;
removing said first mask;
disposing a second mask to cover said surface treatment layer, wherein said second mask has a plurality of patterned openings to expose portions of said substrate;
forming a metal layer on said exposed portions of said substrate;
removing said second mask;
performing a chip package step; and
removing said substrate and said metal layer to form a plurality of fillisters and to expose the side of said surface treatment layer.

10. The fabrication method of the semiconductor package according to claim 9, wherein said patterned openings are formed by laser direct imaging, lithography or image-transfer.

11. The fabrication method of the semiconductor package according to claim 9, wherein said metal layer is formed by electroplating, electroless plating or printing

12. The fabrication method of the semiconductor package according to claim 9, wherein said surface treatment layer is formed by electroplating, chemical plating or printing.

13. The fabrication method of the semiconductor package according to claim 9, wherein said metal layer is removed by etching.

14. The fabrication method of the semiconductor package according to claim 9, wherein the said chip package step comprises:
disposing at least a chip on said surface treatment layer;
electrically connecting said chip and said surface treatment layer; and
forming a molding compound to cover said chip.

15. The fabrication method of the semiconductor package according to claim 14, wherein said chip and said surface treatment layer are electrically connected by wire bonding or flip chip.

16. The fabrication method of the semiconductor package according to claim 9, further comprising a dicing step to form a plurality of semiconductor packages.

17. A semiconductor package structure comprising:
a surface treatment layer defining at least a chip carrier area and a plurality of conducting connection areas around each said chip carrier area;
at least a chip disposed on said chip carrier area and a conducting structure electrically connecting the chip and said conducting connection areas; and
a molding compound directly covering said chip, said conducting structure and said surface treatment layer, wherein a height difference is existed between said surface treatment layer and said molding compound.

18. The semiconductor package structure according to claim 17, wherein said surface treatment layer comprises a plurality of metal films whose material is selected from the group consisting of gold, nickel, palladium, silver, copper, tin and lead.

19. The semiconductor package structure according to claim 17, wherein the material of said surface treatment layer is selected from the group consisting of gold, nickel, palladium, silver, copper, tin and lead.

20. The semiconductor package structure according to claim 17, wherein said conducting structure comprises at least a wire, at least a metal block or at least a connecting pad.

21. The semiconductor package structure according to claim 17, wherein a plurality of fillisters are formed on said chip carrier area and said conducting connection area to expose said surface treatment layer.

22. The semiconductor package structure according to claim 17, wherein a plurality of fillisters are formed around said chip carrier area and said conducting connection area to expose the side of surface treatment layer.

23. The semiconductor package structure according to claim 17, further comprising a plurality of soldering elements disposed on said exposed surface treatment layer.

24. The semiconductor package structure according to claim 23, wherein said fillisters are filled with said soldering elements.

25. The semiconductor package structure according to claim 23, wherein said soldering elements cover said side of surface treatment layer along said fillisters.
